(19) United States
(12) Patent Application Publication
(10) Pub. No.: US 2016/0064320 A1
(43) Pub. Date: Mar. 3, 2016

(54) COUPLING OF AN INTERPOSER TO A PACKAGE SUBSTRATE

(71) Applicant: Cisco Technology, Inc., San Jose, CA (US)

(72) Inventors: Li Li, San Ramon, CA (US); Mohan R. Nagar, Cupertino, CA (US); Jovica Savic, Downer's Grove, IL (US)

(21) Appl. No.: 14/470,670

(22) Filed: Aug. 27, 2014

(51) Int. Cl. H01L 23/498; H01L 23/00; H01L 25/065

(52) U.S. Cl. CPC H01L 23/49838; H01L 23/49894; H01L 25/0655; H01L 24/81; H01L 24/17; H01L 2224/81191; H01L 2924/1579; H01L 2924/157; H01L 2924/15788; H01L 2924/01014; H01L 2924/2064; H01L 2924/20641; H01L 2224/81801; H01L 2224/81203; H01L 2224/16227

(57) ABSTRACT

An integrated circuit chip stack and a method for forming the same in which bond pads of an interposer are directly bonded to bond pads of a package substrate using only pre-solder. The interposer can have a bond pad pitch of less than 150 micrometers. The interposer can be an organic interposer. The pro-solder can be melted to make contact with the bond pads of the package substrate and the interposer. After solidifying, the pre-solder can form an electrical connection between a bond pad of the interposer and a bond pad of the package substrate.

### TECHNICAL FIELD

Embodiments presented in this disclosure generally relate to interposers for use with integrated circuits. More specifically, embodiments disclosed herein couple interposers to substrates and/or printed circuit boards without using controlled collapse chip connection (C4) bumps.

### BACKGROUND

Interposers are often used in combination with integrated circuit (IC) chips to connect the IC chips to a substrate and/or to a printed circuit board (PCB). In various instances, an interposer can connect or couple either a single IC chip or multiple IC chips to a substrate or to a PCB. In various instances, an interposer can connect multiple IC chips in a 2.5 D IC chip stack and/or a 3D IC chip stack. When connecting multiple IC chips, the interposer can include electrical connections that directly connect one or more electrical contacts of a first IC chip with one or more electrical contacts of a second IC chip.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a cross sectional side view of a partially-assembled integrated circuit (IC) stack that includes an interposer with IC chips on a first surface and controlled collapse chip connection (C4) bumps arranged on a second surface, wherein the interposer is arranged above a package substrate prior to being attached to the package substrate.

FIG. 1B is a cross-sectional side view of a partially-assembled integrated circuit (IC) stack that includes an interposer attached to a package substrate using C4 bumps, wherein IC chips are arranged above the interposer prior to being attached to the interposer.

FIG. 1C is a cross-sectional side view the fully assembled IC stack of FIG. 1A or 1B.

FIG. 2A is a cross-sectional side view of a partially-assembled integrated circuit (IC) stack that includes an interposer with IC chips on a first surface and bond pads arranged on a second surface, wherein the interposer is arranged above a package substrate prior to being attached to the package substrate.

FIG. 2B is a cross-sectional side view of a partially-assembled integrated circuit (IC) stack that includes an interposer that has been attached to a package substrate, wherein IC chips are arranged above the interposer prior to being attached to the interposer.

FIG. 2C is a cross-sectional side view of the fully-assembled IC stack of FIG. 2A or 2B.

FIG. 3A is a detailed cross-sectional side view of bond pads of an interposer and package substrate before the interposer has been attached to the package substrate.

FIG. 3B is a detailed cross-sectional side view of the bond pads of the interposer and package substrate of FIG. 3B after the interposer has been attached to the package substrate.

FIG. 4A is a cross-sectional side view of an IC stack that illustrates convective heat being applied to pre-solder and bond pads of an interposer and a package substrate.

FIG. 4B is a cross-sectional side view of the IC stack of FIG. 4A in a partially-assembled state that illustrates convective heat being applied to pre-solder and bond pads of an interposer and a package substrate, wherein IC chips have not been attached to the interposer.

FIG. 5A is a cross-sectional side view of an IC stack that illustrates compressive force and conductive heating being applied to the IC stack.

FIG. 5B is a cross-sectional side view of the IC stack of FIG. 5A in a partially-assembled state that illustrates compressive force and conductive heating being applied to the partially-assembled IC stack, wherein IC chips have not been attached to the interposer.

FIG. 6A is a cross-sectional side view of an IC stack that illustrates compressive force being applied to the IC stack, wherein convective heat and/or conductive heat is being applied to the pre-solder and bond pads of the interposer and package substrate.

FIG. 6B is a cross-sectional side view of the IC stack of FIG. 6A in a partially-assembled state that illustrates compressive force being applied to the partially-assembled IC stack, wherein convective heat and/or conductive heat is being applied to the partially-assembled IC stack, wherein IC chips have not been attached to the interposer.

FIG. 7A illustrates a process for making an IC chip package.

FIG. 7B illustrates another process for making an IC chip package.

To facilitate understanding, identical reference numerals have been used, where possible, to designate identical elements that are common to the figures. It is contemplated that elements disclosed in one embodiment may be beneficially utilized on other embodiments without specific recitation.

### DESCRIPTION OF EXAMPLE EMBODIMENTS

### Overview

In one embodiment presented in this disclosure, a method for providing an integrated circuit (IC) package can include providing an interposer that has a first surface and a second surface opposite the first surface. The first surface can include a first plurality of bond pads and the second surface can include a second plurality of bond pads. A distance or pitch between bond pads of the second plurality of bond pads can be less than 150 μm. The method can also include providing a package substrate that includes a first surface and a second surface opposite the first surface. The first surface of the package substrate can include a third plurality of bond pads with pre-solder arranged thereon. The method can also include attaching electrical connections of at least one integrated circuit chip to the first plurality of bond pads on the first surface of the interposer. The method can also include directly soldering the second plurality of bond pads on the second surface of the interposer to the third plurality of bond pads on the first surface of the package substrate with the solder paste.

In another embodiment presented in this disclosure, an IC package can include an interposer that has a first surface and a second surface opposite the first surface. The first surface can include a first plurality of bond pads and the second surface can include a second plurality of bond pads. The pitch between bond pads of the second plurality of bond pads can be less than 150 μm. The IC package can also include a package substrate that includes a first surface and a second surface opposite the first surface. The first surface can include a third plurality of bond pads, and the second plurality of bond pads on the interposer can be directly soldered to the third plurality of bond pads of the package substrate with pre-solder that was prearranged on the third plurality of bond pads. The IC package can also include at least one integrated circuit chip electrically connected to the first plurality of bond pads on the first surface of the interposer.

In another embodiment presented in this disclosure, an electronic component can include a printed circuit board. The electronic component can also include an interposer that includes a first surface and a second surface opposite first surface. The first surface of the interposer can include a first plurality of bond pads and the second surface of the interposer can include a second plurality of bond pads. The pitch between bond pads of the second plurality of bond pads can be less than 150 μm. The electronic component can also include a package substrate that includes a first surface and a second surface opposite the first surface. The first surface can include a third plurality of bond pads and the second surface of the package substrate can be connected to the printed circuit board by a ball grid array. The third plurality of bond pads of the package substrate can be directly soldered to the second plurality of bond pads of the interposer with pre-solder that was prearranged on the third plurality of bond pads on the package substrate. The electronic component can also include at least one IC chip electrically connected to the first plurality of bond pads on the first surface of the interposer.

### Example Embodiments

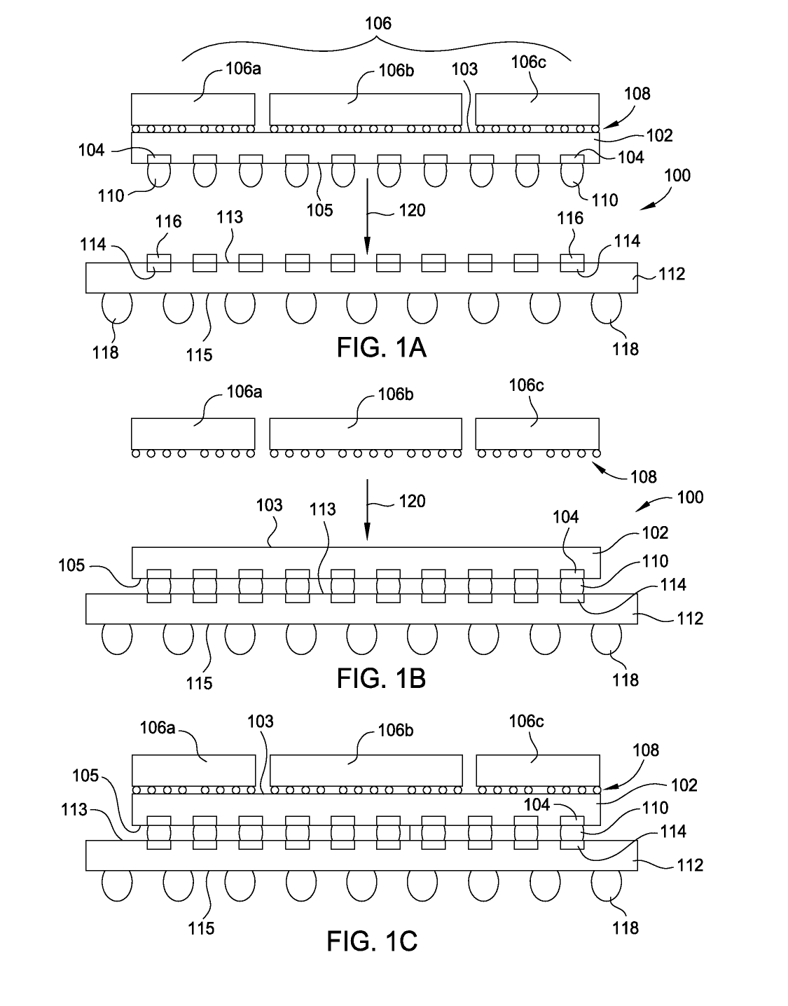

FIGS. 1A through 1C illustrate assembly of a 2.5D and/or 3D IC stack 100. The IC stack 100 includes IC chips 106a, 106b, 106c mounted to an interposer 102. The IC chips 106a, 106b, 106c may be different types of IC chips, such as generic IC chips, application specific IC (ASIC) chips, single die IC chips, or a die stack of IC chips (i.e., 3-D IC chips). The IC chips 106a, 106b, and 106c (referred to collectively as IC chips 106) are attached to the interposer 102 via micro bumps 108. The micro bumps 108 connect electrical bond pads of the IC chips 106, to bond pads on a first surface 103 of the interposer 102. In one embodiment, the interposer includes electrical communication paths between different bond pads on the first surface 103 that enable communication between the different IC chips 106. The interposer 102 may also include vias that extend from the first surface 103 of the interposer 102 to a second surface 105 of the interposer 102. The vias can be in electrical communication with the bond pads on the first surface 103 of the interposer 102 and with bonds pads 104 on the second surface 105 of the interposer 102. In various instances, the bond pads 104 on the second surface 105 of the interposer 102 have controlled collapse chip connection (C4) bumps 110 arranged thereon. The C4 bumps 110 are balls of solder that have been formed or deposited on the bond pads 104 at an earlier time. Typically, C4 bumps 110 have a diameter of at least 150 to 200 μm. In various instances, the bond pads 104 on the second surface 105 of the interposer 102 have copper pillars with solder caps arranged thereon.

As shown, the interposer 102 is mounted to a package substrate 112. In one embodiment, the package substrate 112 is a printed circuit board (PCB). In other embodiments, the package substrate 112 is mounted to a PCB. In this example, the package substrate 112 includes ball grid array (BGA) balls 118 arranged on a second surface 115. Although not shown, the BGA balls 118 can contact electrical connections (e.g., bond pads) on the second surface 115 of the package substrate 112. The package substrate 112 includes a plurality of bond pads 114 arranged on a first surface 113. Each of the bond pads 114 has a layer of pre-solder 116 thereon. The pre-solder 116 can be applied to the bond pads 114 using a stencil, for example, and a thickness of the pre-solder 116 is determined by the thickness of the stencil. For example, stencils often have a thickness of approximately 20 μm, and thus, the thickness of the pre-solder 116 may be around 20 μm. After the pre-solder 116 has been arranged on the bond pads 114 the pre-solder 116 can be heated, such that it melts or flows, and then cooled to re-solidify. Thereafter, the individual pads of pre-solder 116 may be flattened slightly to provide a uniform level surface above the first surface 113 of the package substrate 112.

As shown in FIG. 1A, the interposer 102 is aligned above the package substrate 112 so that the C4 bumps 110 arranged on the interposer 102 are aligned with the bond pads of the package substrate 112 (with the pre-solder 116 thereon). As indicated by the arrow 120, the interposer 102 can then be brought into contact with the package substrate 112. Thereafter, as described in greater detail below, heat can be applied to melt the C4 bumps 110 (and possibly also the pre-solder 116), thereby electrically connecting bond pads 104 of the interposer 102 and bond pads 114 of the package substrate 112 (as shown in FIG. 1C). When the C4 bumps 110 melt, the pre-solder 116 can become intermixed with the melted C4 bump 110 material. Thus, the pre-solder 116 is not shown in FIG. 1C. After the reflow process, the C4 bumps 110 typically provide a gap between the bond pads 104 of the interposer 110 and the bond pads 114 of the package substrate 112 of 70 to 100 μm.

FIG. 1B illustrates an alternate partially-assembled 2.5D/3D IC stack 100 in which the interposer 102 is attached to the package substrate 112 (in the manner described above with reference to FIGS. 1A and 1C) prior to the IC chips 106 being arranged on the interposer 102. Such a partial assembly may be used in instances in which the IC chips 106 and/or the microbumps 108 may sustain damage from temperatures used to re-flow the C4 bumps 110, for example. Such a partial assembly may also be used in assembly processes where the interposer 102 is mounted to the package substrate 112 prior to the IC chips 106 being arranged on the interposer 102. The resulting 2.5D/3D IC stack 100 shown in FIG. 1C can be the same regardless of whether the IC stack 100 is assembled in the order shown in FIG. 1A or the order shown in FIG. 1B. After the interposer 102 is attached to the package substrate 112, the gap therebetween can be underfilled with an encapsulating material that can provide an additional physical connection between the interposer 102 and the package substrate 112, increasing reliability of the connections between the bond pads 104 and 114.

For interposers that include denser arrays of bond pads, the distance or pitch between bond pads may become too small to use C4 bumps because adjacent C4 bumps would touch, causing electrical shorts. For example, for an interposer with a pitch between bond pads less than 150 μm, C4 bumps cannot be used. Furthermore, organic interposers may not be connectable to a package substrate or a PCB with C4 bumps. The processes described below enable organic interposers and/or interposers having a pitch between bond pads less than 150 μm to be connected to a package substrate or a PCB without the use of C4 bumps.

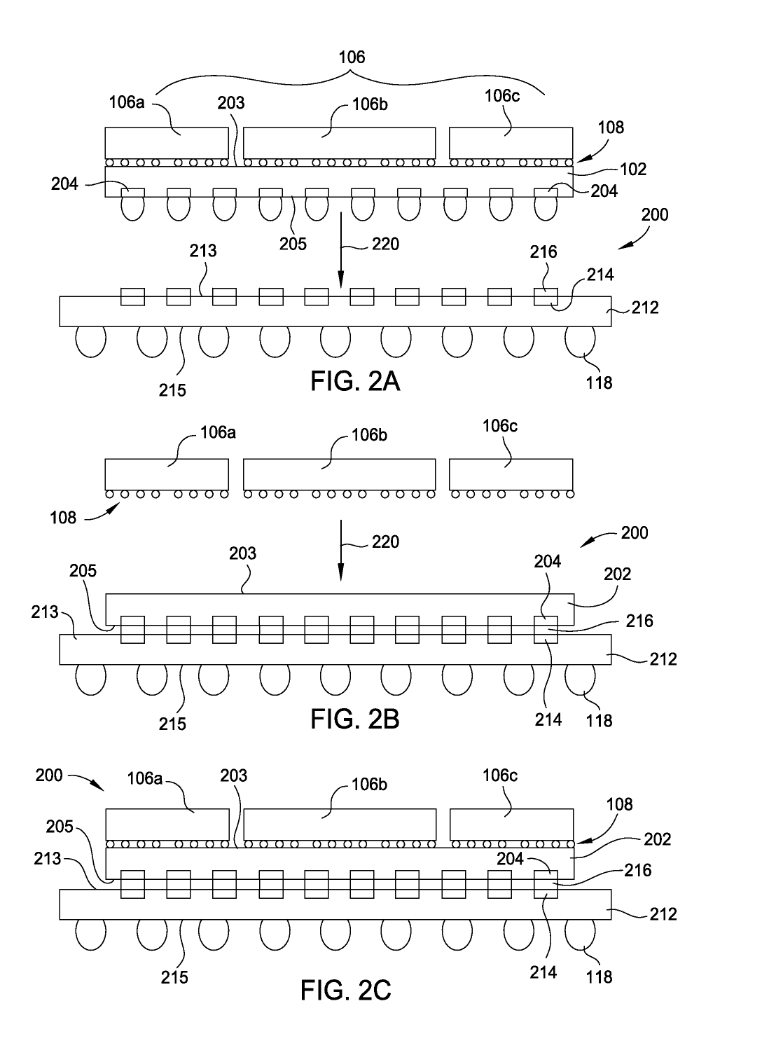

Referring now to FIGS. 2A through 2C, in various embodiments, bond pads 204 of an interposer 202 are directly connected to bond pads 214 of a package substrate 212 using pre-solder 216 (i.e., a solder material). Put differently, the bond pads 204 of the interposer 202 can be connected to the bond pads 214 of the package substrate 212 without using C4 bumps, copper pillars, or the like. The interposer 202 can be a silicon interposer, an organic (e.g., plastic) interposer, or a glass interposer. As an example, an interposer can be a multi-layer interposer composed of multiple conductive layers (e.g., 2, 3, 4, or more layers) and having a thickness of 0.5 millimeters or less. As shown in FIG. 2A, the interposer 202 includes IC chips 106 connected to bond pads on a first surface 203 of the interposer 202 with micro bumps 108. The bond pads 204 on the second surface 205 of the interposer 202 may have a thickness of less than 10 μm. The package substrate 212 includes a plurality of bond pads 214 arranged on a first surface 213. Each of the bond pads 214 includes a layer of pre-solder 216 thereon. As described above, the pre-solder 216 can be applied using a stenciling process, which results in a layer of pre-solder 216 having a thickness of between 5 μm and 100 μm. In various embodiments, the layer of pre-solder 216 can have a thickness less than 50 μm. In various embodiments, the layer of pre-solder 216 can have a thickness less than 30 μm. In various embodiments, the layer of pre-solder 216 can have a thickness of approximately 20 μm. As shown, the package substrate 212 includes BGA balls 218 on a second surface 215 for connections to a printed circuit board, for example.

To form a 2.5D/3D IC stack 200, the interposer 202 is aligned above the package substrate 212 such that the bond pads 204 of the interposer 202 align with the bond pads 214 of the package substrate 212. Then, as indicated by arrow 220, the interposer 202 is brought into contact with the package substrate 212 so that the bond pads 204 of the interposer 202 contact the pre-solder 216. As will be described in greater detail below, the pre-solder 216 can be heated so that it melts and bonds with the bond pads 204 of the interposer 202 and the bond pads 214 of the package substrate 212. Referring to FIG. 2C, in various embodiments, after the pre-solder 216 has been heated, the interposer 202 and the package substrate 212 are separated by a gap approximately equal to the thickness of the layer of pre-solder 216 (e.g., approximately 20 μm). In various embodiments, after the pre-solder 216 has been heated, the interposer 202 and the package substrate 212 are separated by a gap approximately equal to or less than a radius of the bond pads 204 and/or 214.

Referring now to FIG. 2B, in various embodiments, the IC stack 200 is formed by first attaching the interposer 202 to the package substrate 212 (as described above with reference to FIGS. 2A and 2C). Thereafter, IC chips 106 are attached to the interposer 252 using micro bumps 108 (as indicated by arrow 220). The resulting 2.5D/3D IC stack 200 shown in FIG. 2C can be the same regardless of whether the IC stack 200 is assembled in the order shown in FIG. 2A or the order shown in FIG. 2B. After the interposer 202 is attached to the package substrate 212, the gap therebetween can be underfilled with an encapsulating material that can provide an additional physical connection between the interposer 202 and the package substrate 212, increasing reliability of the connections between the bond pads 204 and 214.

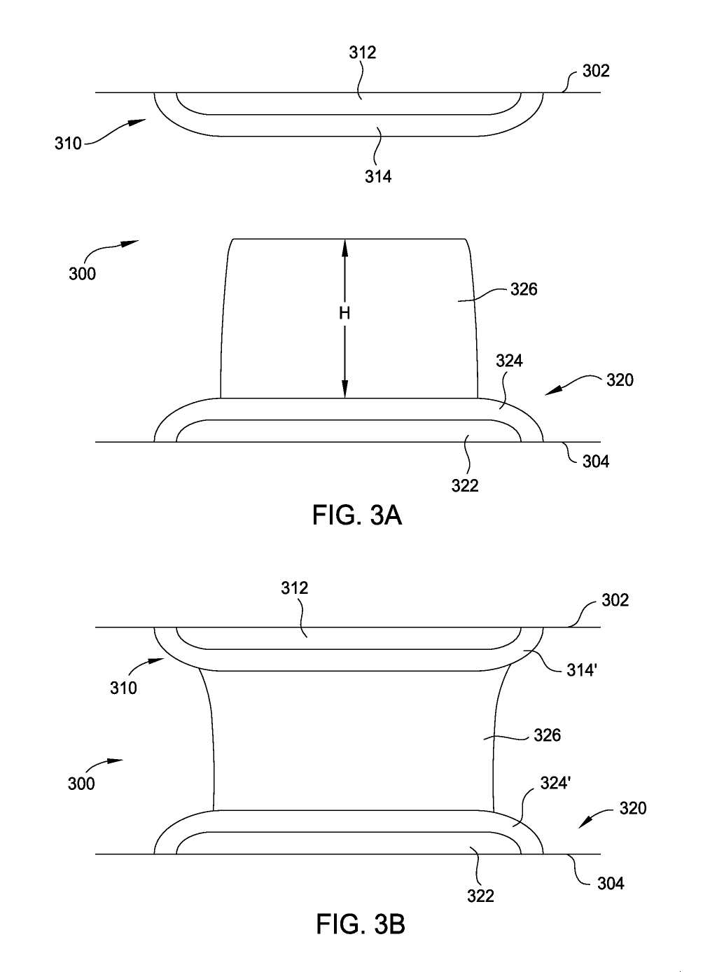

FIGS. 3A and 3B illustrate a detail view of a bond pad 310 of an interposer 302 aligned with a bond pad 320 of a package substrate 304, wherein the bond pad 320 of the package substrate 304 includes a layer of pre-solder 326 thereon. As described above, the pre-solder 326 can define a height H that is a result of the thickness of the stencil used to arrange the pre-solder 326 on the bond pad 320. In one embodiment, the height H of the pre-solder 326 corresponds to the height of the stencil. The bond pad 310 of the interposer 302 can include a base layer 312 of copper and a top layer 314 of nickel, gold nickel, or other alloys. Similarly, the bond pad 320 of the package substrate 304 can include a base layer 322 of copper and a top layer 324 of nickel, gold nickel, or other alloys. In FIG. 3A, the interposer 302 has not moved into position such that the bond pad 310 contacts the pre-solder 326. In FIG. 3B, the interposer 302 has moved such that the bond pad 310 contacts the pre-solder 326, and the pre-solder 326 has been heated to form a mechanical and electrical connection between the bond pads 310 and 320. In one embodiment, the base layers 312 and 322 of the bond pads 310 and 320 may remain substantially unchanged after the pre-solder 326 has been heated. In one example, at least a portion of the top layers 314 and 324 transforms into an intermetallic region, denoted by reference numbers 314′ and 324′. For example, a nickel or gold nickel alloy from the top layer 314 may mix with tin and/or silver in the pre-solder 326 to form the intermetallic region 314′ on the bond pad 310 on the interposer 302. Similarly, a nickel or gold nickel alloy from the top layer 324 may mix with tin and/or silver in the pre-solder 326 to form the intermetallic region 324′ on the bond pad 320.

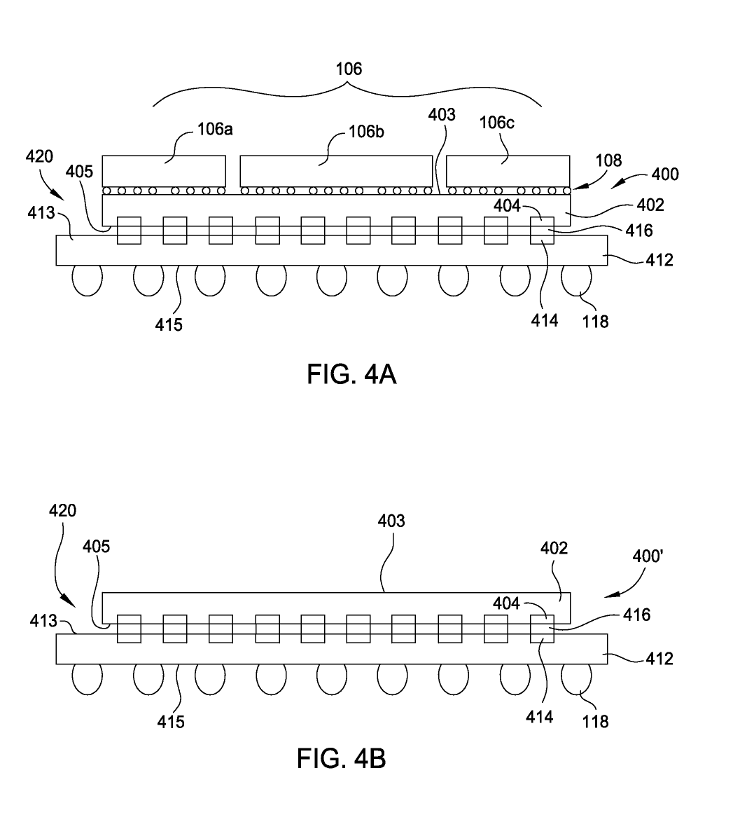

FIGS. 4A, 4B, 5A, 5B, 6A, and 6B illustrate embodiments of processes for heating pre-solder to bond the bond pads of an interposer to bond pads of a package substrate. Referring to FIGS. 4A and 4B, pre-solder 416 in contact with bond pads 404 of an interposer 402 and bond pads 414 of a package substrate 412 can be heated by applying hot gas 420. As shown in FIG. 4A, hot gas 420 (e.g., air or an inert gas such as nitrogen) can be directed toward an IC stack 400 to convectively heat all or portions of the IC stack 400. In various instances, the hot gas 420 is applied to the entire IC stack 400. In various other instances, the hot gas 420 is directed between the second surface 205 of the interposer 402 and the first surface 413 of the package substrate 412 to target the application of heat on the pre-solder 416 and the bond pads 404 of the interposer 402 and the bond pads 414 of the package substrate 412. As shown in FIG. 4B, hot gas 420 is applied to a partially-assembled IC stack 400′ prior to the IC chips 106 being arranged on the interposer 402.

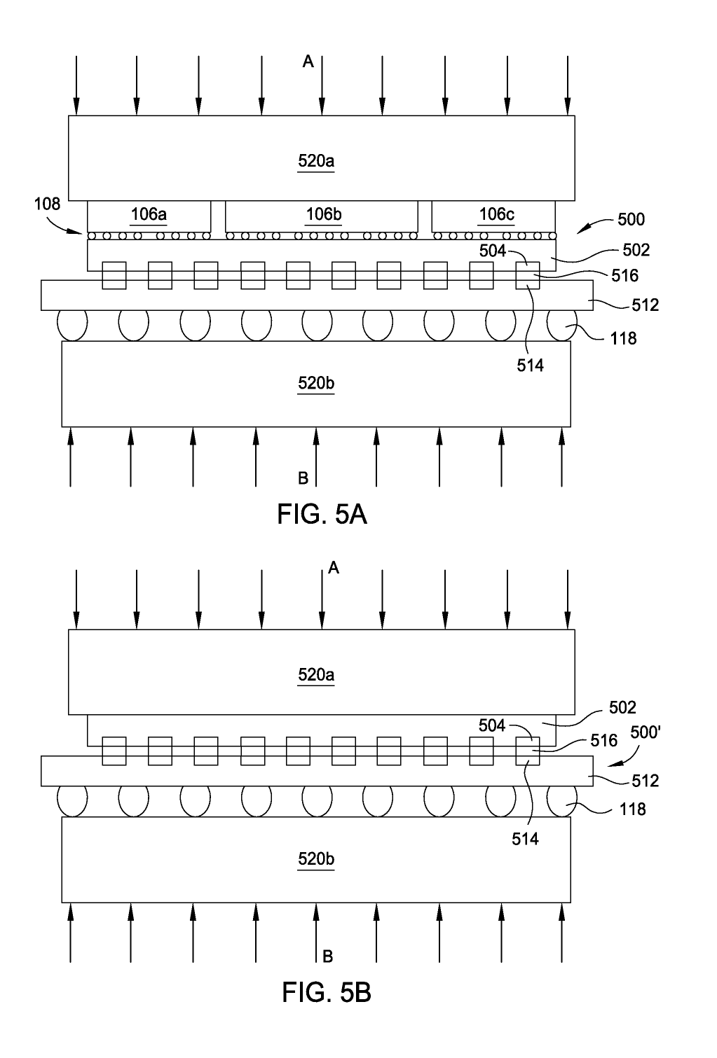

Referring now to FIGS. 5A and 5B, pre-solder 516 that couples bond pads 504 of an interposer 502 to bond pads 514 of a package substrate 512 can be heated in parallel with an with application of compressive force. As shown in FIG. 5A, an IC stack 500 can be placed between clamping blocks 520a and 520b, which provide the compressive force as indicated by arrows A and B. This compressive force may compensate for any warping and/or surface waviness of the interposer 502 and/or package substrate 512, ensuring that each of the bond pads 504 of the interposer 502 contact the pre-solder 516 on the respective bond pads 514 of the package substrate 512. Additionally, heat can be applied to the IC stack 500 through the clamping blocks 520a and 520b. For example, the clamping blocks 520a and 520b can be heated, and the heat is conducted to the IC stack 500 to heat the pre-solder 516. Alternatively or additionally, the clamping blocks 520a and 520b may transmit ultrasonic vibrations to the IC stack 500 which heat the pre-solder 516. As shown in FIG. 5A, the IC stack 500 can include IC chips 106 already arranged on the interposer 502 when the IC stack 500 is placed between the clamps 520a and 520b. Alternatively, as shown in FIG. 5B, a partially-assembled IC stack 500′ that does not include the IC chips 106 arranged on the interposer 552 can also be placed between the clamping blocks 520a and 520b.

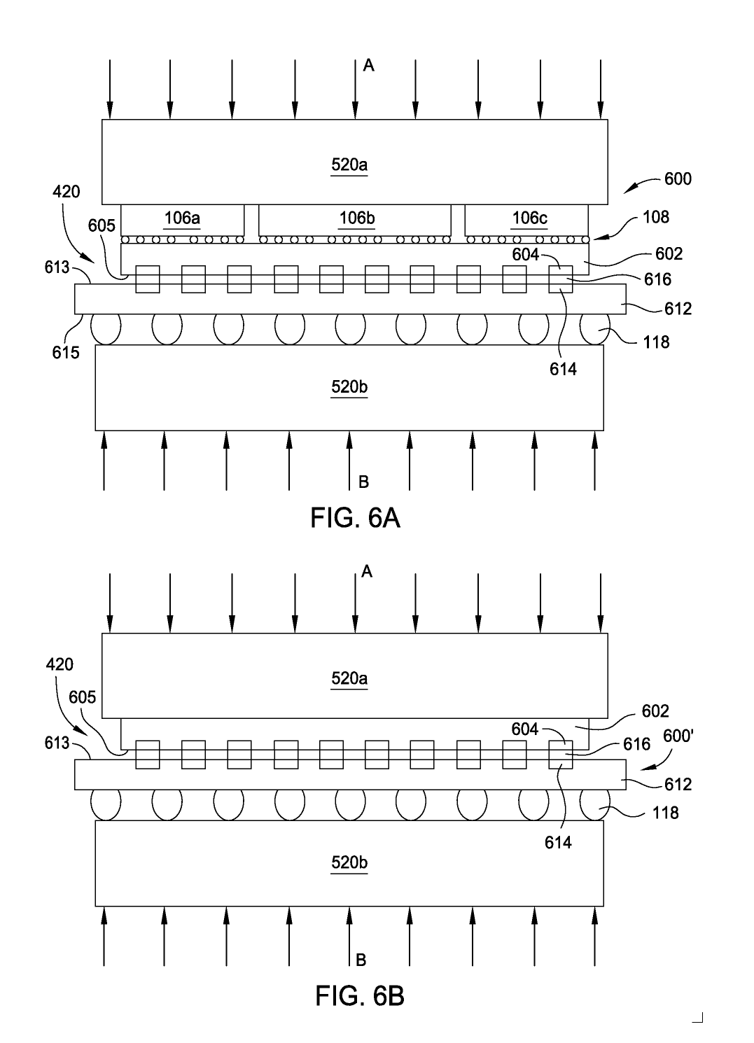

Referring now to FIGS. 6A and 6B, pre-solder 616 that couples bond pads 604 of an interposer 602 to bond pads 614 of a package substrate 612 is heated by applying compressive force in combination with conductive heating (via the clamping blocks 520a and 520b) and/or hot gas 420. Referring to FIG. 6A, an IC stack 600 can be placed between clamping blocks 520a and 520b, which can apply a compressive force (indicated by arrows A and B) to the IC stack 600. Then, hot gas 420 can be applied (as discussed above with reference to FIGS. 4A and 4B) to apply convective heat to the pre-solder 616. Alternatively to or in combination with applying the hot gas 420, heat can be applied to the pre-solder 616 conductively through the clamping blocks 520a and 520b and/or through ultrasonic energy transmitted through the clamping blocks 520a and 520b (as discussed above with reference to FIGS. 5A and 5B). Alternatively, referring to FIG. 6B, a partially-assembled IC stack 600′ that does not include the IC chips 106 arranged on the interposer 602 can also be placed between the clamping blocks 520a and 520b.

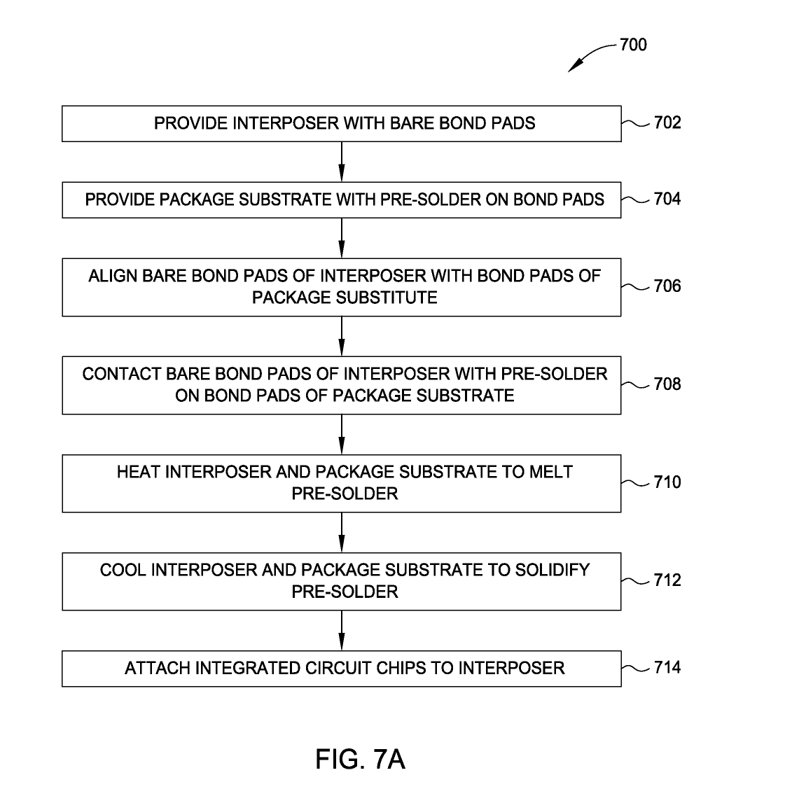

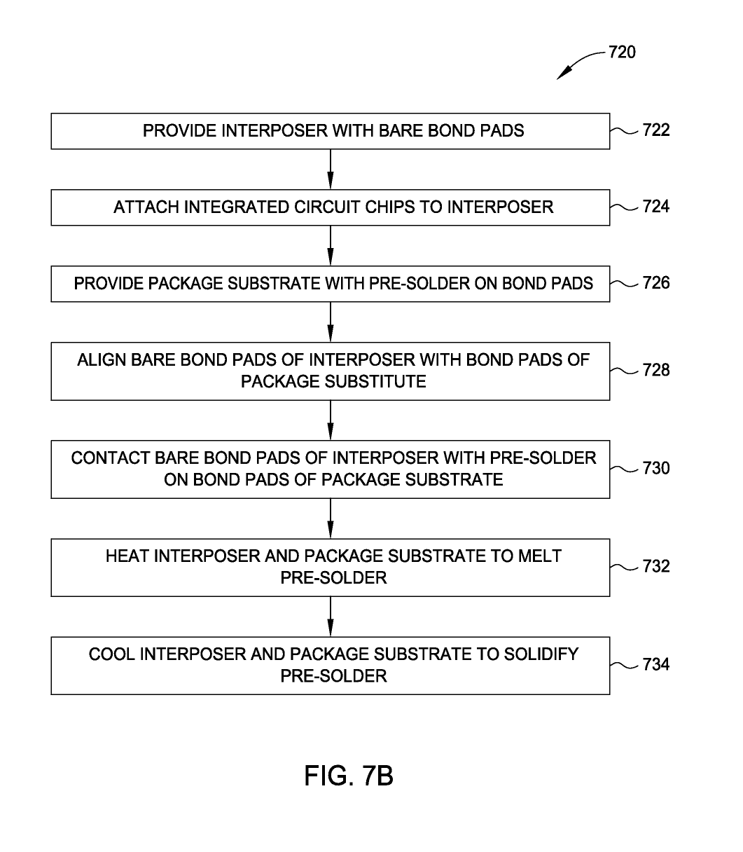

FIG. 7A provides a process 700 for assembling an IC stack (e.g., IC stack 200 shown in FIG. 2C. At block 704, a package substrate (e.g., package substrate 212) is provided with pre-solder (e.g., pre-solder 216) pre-applied on bond pads (e.g., bond pads 214). At block 706, the interposer is aligned above the package substrate such that the bare bond pads of the interposer align with the bond pads (with the pre-solder pre-arranged thereon) of the package substrate. At block 708, the interposer and package substrate can be brought together such that the bare bond pads of the interposer contact the pre-solder on the bond pads of the package substrate. In various embodiments, the pre-solder can be pre-applied on bond pads (e.g., bond pads 204) of the interposer instead of being applied to the bond pads of the package substrate. In such embodiments, at block 708, the interposer and package substrate can be brought together such that the bare bond pads of the package substrate contact the pre-solder on the bond pads of the interposer. In various other embodiments, the pre-solder can be pre-applied on bond pads of both the interposer and the package substrate. In such embodiments, at block 708, the interposer and package substrate can be brought together such that the pre-solder on the bond pads of the interposer contacts the pre-solder on the bond pads of the package substrate. As used herein, the term “pre-applied” means that the pre-solder is applied to bond pads some time before the process 700. For example, the pre-solder may be applied when the interposer and/or package substrate are manufactured. As another example, the pre-solder may be applied immediately before the process 700 is started. At block 710, the interposer and package substrate is heated (e.g., as discussed in FIG. 4B, 5B, or 6B) to melt the pre-solder, creating an electrical bond between the bond pads of the interposer and bond pads of the package substrate. After the pre-solder has melted, the interposer and package can be cooled in block 712 to solidify the pre-solder. The package substrate and interposer may be exposed to ambient temperatures to allow for cooling. The package substrate and interposer may also be quenched (e.g., by exposing the interposer and package substrate to cold air) to rapidly cool the pre-solder. At block 714, after the pre-solder has cooled, IC chips (e.g., IC chips 106 in FIG. 2C) can be attached to the interposer.

FIG. 7B illustrates a process 720 for assembling an IC stack (e.g., IC stack 200 shown in FIG. 2C). At block 714, IC chips (e.g., IC chips 106 in FIG. 2C) can be attached to the interposer. At block 726, a package substrate (e.g., package substrate 212) is provided with pre-solder (e.g., pre-solder 216) pre-applied on bond pads (e.g., bond pads 214). At block 728, the interposer is aligned above the package substrate such that the bare bond pads of the interposer align with the bond pads (with the pre-solder pre-arranged thereon) of the package substrate. At block 730, the interposer and package substrate are brought together such that the bare bond pads of the interposer contact the pre-solder on the bond pads of the package substrate. In various embodiments, the pre-solder can be pre-applied on bond pads (e.g., bond pads 204) of the interposer instead of being applied to the bond pads of the package substrate. In such embodiments, in block 730, the interposer and package substrate can be brought together such that the bare bond pads of the package substrate contact the pre-solder on the bond pads of the interposer. In various other embodiments, the pre-solder can be pre-applied on bond pads of both the interposer and the package substrate. In such embodiments, in block 730, the interposer and package substrate can be brought together such that the pre-solder on the bond pads of the interposer contacts the pre-solder on the bond pads of the package substrate. At block 732, the interposer and package substrate are heated (e.g., as discussed in FIG. 4B, 5B, or 6B) to melt the solder paste, creating an electrical bond between the bond pads of the interposer and bond pads of the package substrate. After the pre-solder has melted, the interposer and package are cooled at block 732 to solidify the solder paste. The package substrate and interposer may be exposed to ambient temperatures to allow for cooling. The package substrate and interposer may also be quenched (e.g., by exposing the interposer and package substrate to cold air) to rapidly cool the solder paste.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions.

The embodiments described herein are advantageous because they enable an organic interposer to be connected to a package substrate and they enable interposers with bond pad pitches of less than 150 μm to be connected to package substrates. Furthermore, the embodiments described herein provide for a simplified process by eliminating the need to form C4 bumps, or the like, on an interposer prior to assembling the interposer and a package substrate.

1. A method for forming an integrated circuit (IC) package, comprising:
providing an interposer that includes a first surface and a second surface opposite the first surface, wherein the first surface includes a first plurality of bond pads, and wherein the second surface includes a second plurality of bond pads;
providing a package substrate that includes a third surface and a fourth surface opposite the third surface, wherein the third surface includes a third plurality of bond pads with pre-solder arranged thereon;
attaching electrical connections on at least one IC chip to the first plurality of bond pads on the first surface of the interposer;
directly contacting the second plurality of bond pads on the second surface of the interposer to the pre-solder on the third plurality of bond pads on the third surface of the package substrate; and
soldering the second plurality of bond pads to the third plurality of bond pads using the pre-solder.

2. The method of claim 1, wherein the interposer comprises an organic interposer.

3. The method of claim 1, wherein the interposer comprises one of: a silicon interposer and a glass interposer.

4. The method of claim 1, wherein at least a portion of the second plurality of bond pads on the second surface of the interposer define a pitch that is less than 150 micrometers.

5. The method of claim 1, wherein directly contacting the second plurality of bond pads on the second surface of the interposer to the plurality of bond pads on the third surface of the package substrate with the pre-solder comprises aligning the interposer and the package substrate such that the second plurality of bond pads on the second surface of the interposer align with the third plurality of bond pads on the third surface of the package substrate; and
wherein soldering the second plurality of bond pads to the third plurality of bond pads using the pre-solder comprises:
applying convective heat so that the pre-solder melts and bonds to respective the second plurality of bonds pads on the second surface of the interposer and the third plurality of bond pads on the third surface of the package substrate; and
cooling the melted pre-solder until the pre-solder solidifies.

6. The method of claim 1, wherein directly contacting the second plurality of bond pads on the second surface of the interposer to the third plurality of bond pads on the first surface of the package substrate with the pre-solder comprises aligning the interposer and the package substrate such that the second plurality of bond pads on the second surface of the interposer align with the plurality of bond pads on the first surface of the package substrate; and
wherein soldering the second plurality of bond pads to the third plurality of bond pads using the pre-solder comprises:
applying a compressive force to squeeze the aligned interposer and package substrate together;
applying heat so that the pre-solder melts and bonds to the second plurality of bonds pads on the second surface of the interposer and the third plurality of bond pads on the first surface of the package substrate; and
cooling the melted pre-solder until the pre-solder solidifies.

7. The method of claim 6, wherein applying heat comprises applying convective heat.

8. The method of claim 6, wherein applying a compressive force to squeeze the aligned interposer and package substrate together comprises applying clamping blocks to the first surface of the interposer and to the second surface of the package substrate; and
wherein applying heat comprises heating the clamping blocks.

9. An integrated circuit (IC) package, comprising:
an organic interposer that includes a first surface and a second surface opposite the first surface, wherein the first surface includes a first plurality of bond pads, and wherein the second surface includes a second plurality of bond pads;
a package substrate that includes a third surface and a fourth surface opposite the third surface, wherein the third surface includes a third plurality of bond pads, and wherein the second plurality of bond pads on the second surface of the interposer is directly contact the third plurality of bond pads on the third surface of the package substrate with only a solder material having a thickness of between 10 and 100 microns; and
at least one integrated circuit chip electrically connected to the first plurality of bond pads on the first surface of the interposer.

10. The IC package of claim 9, wherein the second plurality of bond pads define a pitch of less than 150 microns.

11. The IC package of claim 9, wherein the at least one integrated circuit chip comprises a first IC chip and a second IC chip, and wherein the interposer includes at least one electrical pathway connecting the first IC chip to the second IC chip.

12. The IC package of claim 9, wherein the second plurality of bond pads on the second surface of the interposer are separated from respective ones of the third plurality of bond pads on the third surface of the package substrate by a layer of solder material having a thickness of less than 50 micrometers.

13. The IC package of claim 9, wherein the second plurality of bond pads on the second surface of the interposer are separated from respective ones of the third plurality of bond pads on the third surface of the package substrate by a layer of solder material having a thickness of less than 25 micrometers.

14. An electronic component, comprising:
a printed circuit board;
an interposer that includes a first surface and a second surface opposite the first surface, wherein the first surface includes a first plurality of bond pads, wherein the second surface includes a second plurality of bond pads, wherein a pitch between at least a portion of the second plurality of bond pads is less than 150 micrometers;
a package substrate that includes a third surface and a fourth surface, wherein the third surface includes a third plurality of bond pads arranged thereon, wherein the fourth surface of the package substrate is connected to the printed circuit board by a ball grid array, and wherein the second plurality of bond pads on the second surface of the interposer are directly connected to the third plurality of bond pads on the third surface of the package substrate with a solder material having a thickness of less than 100 micrometers; and
at least one integrated circuit chip electrically connected to the first plurality of bond pads on the first surface of the interposer.

15. The electronic component of claim 14, further comprising:
a second interposer that includes a fifth surface and a sixth surface opposite the fifth surface, wherein the fifth surface of the second interposer includes a fifth plurality of bond pads, wherein the sixth surface includes a sixth plurality of bond pads, wherein a pitch between at least a portion of the sixth plurality of bond pads is less than 150 micrometers;
a second package substrate that includes a seventh surface and an eighth surface, wherein the seventh surface of the second package substrate includes a seventh plurality of bond pads arranged thereon, wherein the eighth surface of the second package substrate is connected to the circuit board by a ball grid array, and wherein the sixth plurality of bond pads on the sixth surface of the second interposer are directly connected to the seventh plurality of bond pads on the seventh surface of the second package substrate with a solder material having a thickness of less than 100 micrometers; and
a second at least one integrated circuit chip electrically connected to the first plurality of bond pads on the first surface of the second interposer.

16. The electronic component of claim 14, wherein the interposer comprises one of: a silicon interposer and a glass interposer.

17. The electronic component of claim 14, wherein the interposer comprises an organic interposer.

18. The electronic component of claim 14, wherein the at least one IC chip comprises a first IC chip and a second IC chip, and wherein the interposer comprises at least one electrical connection between the first IC chip and the second IC chip.

19. The electronic component of claim 14, wherein the second plurality of bond pads on the second surface of the interposer are separated from respective ones of the third plurality of bond pads on the third surface of the package substrate by a layer of solder material having a thickness of less than 50 micrometers.

20. The electronic component of claim 14, wherein the second plurality of bond pads on the second surface of the interposer are separated from respective ones of the third plurality of bond pads on the third surface of the package substrate by a layer of solder material having a thickness of less than 25 micrometers.
